(19) United States
(12) Patent Application Publication
(10) Pub. No.: US 2020/0218155 A1
(43) Pub. Date: Jul. 9, 2020

(54) PHOTORESIST DISPENSING MODULE AND PHOTORESIST COATING SYSTEM HAVING THE SAME

(71) Applicant: XIA TAI XIN SEMICONDUCTOR (QING DAO) LTD., Qingdao (CN)

(72) Inventors: JONG-KILL LIM, Singapore (SG); SUNGKUN JANG, Singapore (SG); JAE-SIK KIM, Singapore (SG)

(21) Appl. No.: 16/661,963

(22) Filed: Oct. 23, 2019

Related U.S. Application Data
(60) Provisional application No. 62/784,544, filed on Dec. 24, 2018.

(51) Int. Cl. G03F 7/16; H01L 21/027; H01L 21/02

(52) U.S. Cl. CPC G03F 7/162; H01L 21/02282; H01L 21/0273

(57) ABSTRACT

The present disclosure provides a photoresist dispensing module for dispensing a photoresist solution onto a wafer. The photoresist dispensing module includes a first nozzle, a second nozzle, and a photoresist pipeline assembly coupled to the first nozzle and the second nozzle. The first nozzle is configured to dispense the photoresist solution to a first portion of the wafer. The second nozzle is configured to dispense the photoresist solution to a second portion of the wafer. The photoresist pipeline assembly is configured to supply the photoresist solution to the first nozzle and the second nozzle.

### CROSS-REFERENCE TO RELATED APPLICATION(S)

This application claims to the benefit of U.S. Provisional Patent Application No. 62/784544 filed on Dec. 24, 2018, the contents of which are incorporated by reference herein.

### FIELD

The present disclosure generally relates to a photoresist dispensing module and a photoresist coating system having the same. More specifically, the present disclosure relates to a photoresist dispensing module having two dispensing nozzles that can reduce the usage of photoresist and enhance the uniformity of a photoresist layer on a wafer.

### BACKGROUND

Generally, photolithography is used to form and pattern a photosensitive layer (or a photoresist layer) on a semiconductor wafer. A photolithography process entails coating the semiconductor wafer with a layer of photoresist, exposing the layer of photoresist and then developing the exposed photoresist.

Spin coating process is often used to form a photoresist layer on the wafer. The spin coating process is commonly performed by dispensing a photoresist solution containing a photoresist material on a central portion of the wafer. Then, the wafer is rotated at a high spinning rate to facilitate uniform spreading of the photoresist solution outward from the center of the wafer (due to centrifugal force), thereby coating the photoresist material over the entire wafer top surface.

During the spin coating process, most of the photoresist is dispensed on the central portion of the wafer then spread out (due to high spinning rate). Reducing photoresist usage for cost reduction may induce fingering effect due to incomplete coverage of the photoresist at the edge portion of the wafer. The fingering effect is shown in FIGS. 1A and 1B. FIGS. 1A and 1B are a schematic view and a partially enlarged cross-sectional view of a wafer 110 coated with a photoresist layer 120. As shown in FIGS. 1A and 1B, the photoresist layer 120 has incomplete coverage of the photoresist at the edge portion of the wafer 110. In order to reduce the fingering effect, an excess amount of photoresist solution needs to be used in the spin coating process.

Accordingly, there remains a need to reduce the usage of photoresist solution and enhance the uniformity of the photoresist layer.

### SUMMARY

In view of above, an object of the present disclosure is to provide a photoresist dispensing module and a photoresist coating system to enhance the uniformity of photoresist coating.

To achieve the above object, an implementation of the present disclosure provides a photoresist dispensing module for dispensing a photoresist solution onto a wafer. The photoresist dispensing module includes a first nozzle, a second nozzle, and a photoresist pipeline assembly coupled to the first nozzle and the second nozzle. The first nozzle is configured to dispense the photoresist solution to a first portion of the wafer. The second nozzle is configured to dispense the photoresist solution to a second portion of the wafer. The photoresist pipeline assembly is configured to supply the photoresist solution to the first nozzle and the second nozzle.

To achieve the above object, another implementation of the present disclosure provides a photoresist coating system for coating a photoresist solution onto a wafer. The photoresist coating system includes a spin cup, a chuck, and a photoresist dispensing module. The spin cup is configured to accommodate the wafer. The chuck is configured to hold the wafer. The photoresist dispensing module is configured to dispense the photoresist solution onto the wafer. The photoresist dispensing module includes a first nozzle, a second nozzle, and a photoresist pipeline assembly coupled to the first nozzle and the second nozzle. The first nozzle is configured to dispense the photoresist solution to a first portion of the wafer. The second nozzle is configured to dispense the photoresist solution to a second portion of the wafer. The photoresist pipeline assembly is configured to supply the photoresist solution to the first nozzle and the second nozzle.

To achieve the above object, yet another implementation of the present disclosure provides a method for spin coating a photoresist solution onto a wafer. The method includes several actions: The wafer is loaded to a photoresist coating system. The photoresist coating system includes a spin cup for accommodating the wafer, a chuck configured to hold the wafer, and a photoresist dispensing module configured to dispense the photoresist solution onto the wafer. The photoresist dispensing module includes a first nozzle and a second nozzle. A thinner solution is dispensed from a thinner module to rinse the wafer. The first nozzle and the second nozzle are moved to predetermined positions above the wafer. The photoresist solution is dispensed to a first portion of the wafer by the first nozzle and to a second portion of the wafer by the second nozzle. The wafer W is rotated on the chuck of the photoresist coating system to spread the photoresist solution over the surface of the wafer by centrifugal force. Edge beads formed at a bevel and backside of the wafer from the photoresist solution is cleaned by an edge bead removal (EBR) module of the photoresist coating system. The wafer is unloaded from the photoresist coating system.

As described above, the photoresist coating system and the method of the implementations of the present disclosure use an extra nozzle to dispense photoresist solution on the edge portion of the wafer. Therefore, the photoresist coating system and method of the implementations of the present disclosure can reduce the usage of photoresist solution, and also improve the uniformity of photoresist coating by reducing fingering effect on the edge of the wafer.

### BRIEF DESCRIPTION OF THE DRAWINGS

Implementations of the present technology will now be described, by way of example only, with reference to the attached figures.

FIGS. 1A and 1B are a schematic view and a partially enlarged cross-sectional view of fingering effect of a wafer coated with a photoresist layer.

FIG. 2A is a schematic diagram of a photoresist coating system according to an implementation of the present disclosure; FIG. 2B is a top view showing a first nozzle and a second nozzle of a photoresist dispensing module of the photoresist coating system in FIG. 2B; FIG. 2C is a schematic diagram showing an example of positions of the first nozzle and the second nozzle of FIG. 2B.

FIG. 3A is a schematic diagram of the photoresist coating system according to another implementation of the present disclosure; FIGS. 3B and 3C are tops views of the first nozzle and the second nozzle of the photoresist coating system according to various implementations of the present disclosure.

FIG. 4 is a flow chart of a method for spin coating a photoresist solution onto a wafer according to an implementation of the present disclosure.

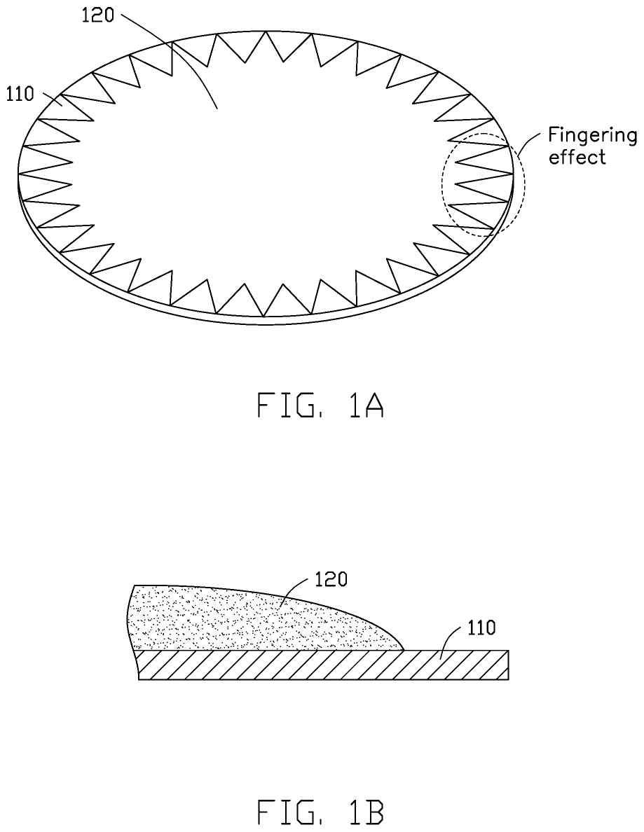

### DETAILED DESCRIPTION

The present disclosure will now be described more fully hereinafter with reference to the accompanying drawings, in which exemplary implementations of the disclosure are shown. This disclosure may, however, be embodied in many different forms and should not be construed as limited to the exemplary implementations set forth herein. Rather, these exemplary implementations are provided so that this disclosure will be thorough and complete, and will fully convey the scope of the disclosure to those skilled in the art. Like reference numerals refer to like elements throughout.

The terminology used herein is for the purpose of describing particular exemplary implementations only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, steps, operations, elements, and/or components, but do not preclude the presence or addition of one or more other features, regions, integers, steps, operations, elements, components, and/or groups thereof.

It will be understood that the term “and/or” includes any and all combinations of one or more of the associated listed items. It will also be understood that, although the terms first, second, third etc. may be used herein to describe various elements, components, regions, parts and/or sections, these elements, components, regions, parts and/or sections should not be limited by these terms. These terms are only used to distinguish one element, component, region, part or section from another element, component, region, layer or section. Thus, a first element, component, region, part or section discussed below could be termed a second element, component, region, layer or section without departing from the teachings of the present disclosure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

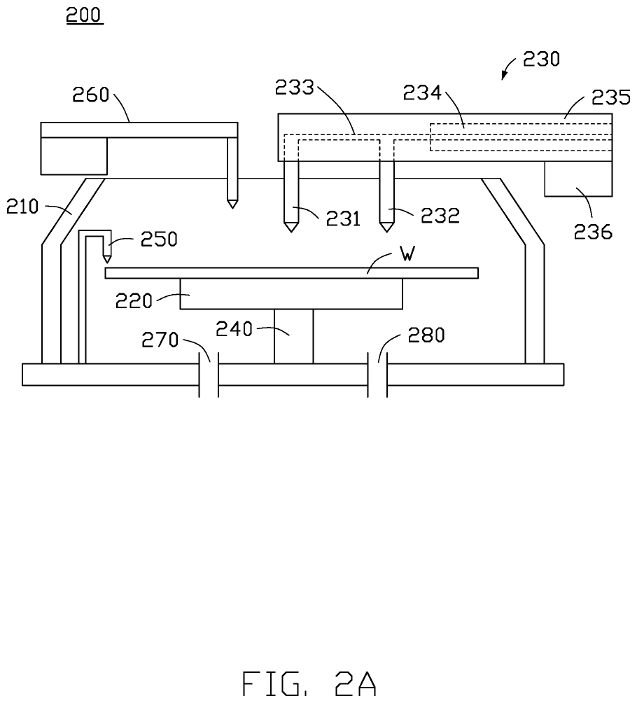

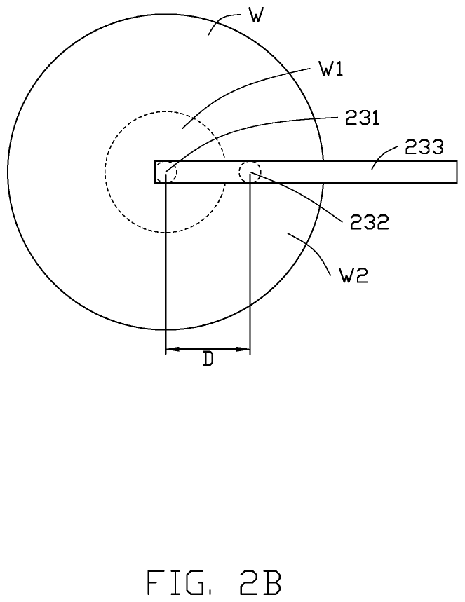

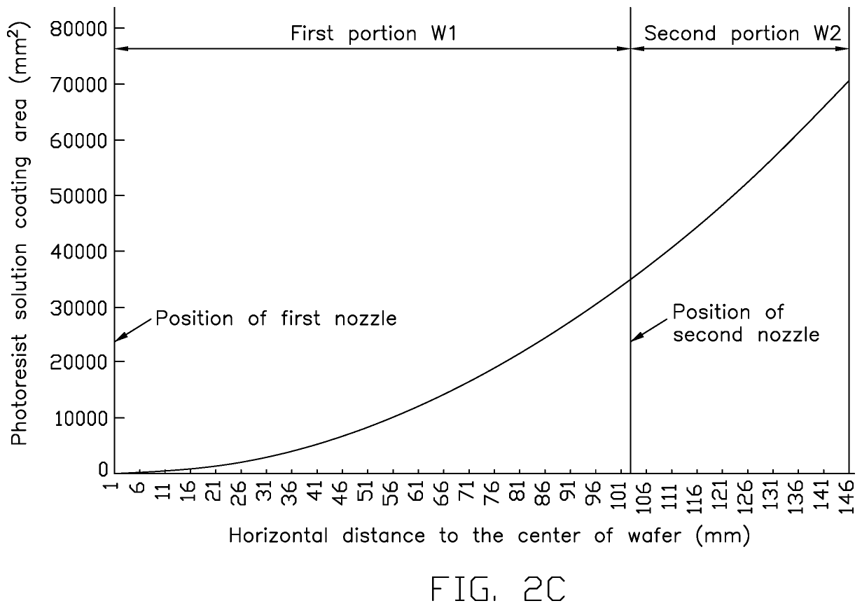

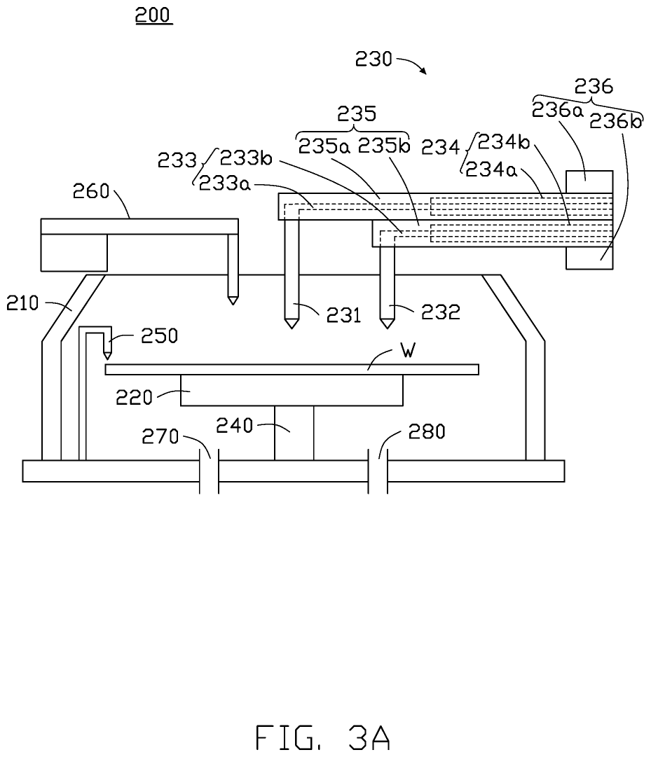

The description will be made as to the exemplary implementations of the present disclosure in conjunction with the accompanying drawings in FIGS. 2A to 4. Reference will be made to the drawing figures to describe the present disclosure in detail, wherein depicted elements are not necessarily shown to scale and wherein like or similar elements are designated by same or similar reference numeral through the several views and same or similar terminology.

The present disclosure will be further described hereafter in combination with the accompanying figures.

Referring to FIG. 2A, a schematic diagram of a photoresist coating system 200 is illustrated. As shown in FIG. 2A, the photoresist coating system 200 includes a spin cup 210 that has a bowl-like shape arranged to receive a semiconductor wafer W and to prevent liquids from spreading out during spin coating process. The photoresist coating system 200 also includes a photoresist dispensing module 230 to provide a photoresist solution onto a top surface of the wafer W. The wafer W is retained on a chuck 220 during the spin coating process. The wafer is rotated at a high spinning rate on the chuck 220 to facilitate uniform spreading of the photoresist solution outward from the center of the wafer W to the edge of the wafer W. The photoresist coating system 200 further includes a thinner dispensing module 260, an edge bead removal (EBR) module 250, and a spin motor 240. The thinner dispensing module 260 is configured to dispense a thinner solution, such as propylene glycol methyl ether acetate (PGMEA), onto the wafer W to rinse the surface of the wafer W before dispensing the photoresist solution. The EBR module 250 is disposed in the spin cup 210 and is configured to clean edge beads formed by excess photoresist solution at the bevel and the backside of the wafer W. The spin motor 240 is coupled to the chuck 220 to rotate the wafer W held by the chuck 220. The photoresist coating system 200 may further include a drain hole 270 and an exhaust hole 280 disposed at a bottom of the spin cup 210. The drain hole 270 is configured to drain liquids (such as excess photoresist solution or thinner solution) out of the spin cup 210 during the spin coating process. The exhaust hole 280 is configured to exhaust air out of the spin cup 210 to prevent particles in the air from contaminating the wafer W.

The photoresist dispensing module 230 of the photoresist coating system 200 includes a first nozzle 231 and a second nozzle 232, a photoresist pipeline assembly 233, a water sleeve assembly 234, a dispensing arm assembly 235, and an arm motor assembly 236. The first nozzle 231 and the second nozzle 232 are configured to respectively dispense the photoresist solution at a first portion and a second portion of the wafer. The first nozzle 231 and the second nozzle 232 may have a diameter within a range of 0.5 mm to 0.8 mm. The photoresist pipeline assembly 233 is coupled to the first nozzle 231 and the second nozzle 232 and configured to supply the photoresist solution to the first nozzle 231 and the second nozzle 232. The photoresist pipeline assembly 233 is surrounded by the wafer sleeve assembly 234 to enable temperature control of the photoresist solution inside the photoresist pipeline assembly 233. The dispensing arm assembly 235 is coupled to the photoresist pipeline assembly 233 and is driven by the arm motor assembly 236 to move the first nozzle 231 and the second nozzle 232 to a predetermined position above the wafer W.

Referring to FIG. 2B, a top view of the wafer W and the first nozzle 231 and the second nozzle 232 of the photoresist dispensing module 230 is illustrated. As shown in FIGS.

2A and 2B, the first nozzle 231 is configured to dispense the photoresist solution to a first portion W1 of the wafer W; and the second nozzle 232 is configured to dispense the photoresist solution to a second portion W2 of the wafer. In this implementation, the first portion W1 is a center portion of the wafer W indicated as an area defined by the dashed circle in FIG. 2B; and the second portion W2 is an edge portion of the wafer W indicated as an area between the dashed circle and the edge of the wafer W. Since the second nozzle 232 is configured to dispense the photoresist solution at the edge portion of the wafer W, the uniformity of the photoresist layer formed on the surface of the wafer W can be improved. Also, the amount of photoresist solution used in the process can be reduced, as well as preventing the fingering effect on the edge portion of the wafer W.

In the implementation shown in FIGS. 2A and 2B, the first nozzle 231 and the second nozzle 232 are connected to a single-pipe photoresist pipeline assembly 233. The dispensing arm assembly 235 moves the photoresist pipeline assembly 233 so that the first nozzle 231 and the second nozzle 232 are moved to a predetermined position above the wafer W. In the implementation shown in FIG. 2B, the first nozzle 231 is moved to a center position above the wafer W; and the second nozzle 232 is moved to a peripheral position relative to the center position above the wafer W. The first nozzle 231 and the second nozzle 232 are spaced apart for a horizontal distance D. The horizontal distance D between the first nozzle 231 and the second nozzle 232 may be decided by an equation

$$D = \sqrt{\frac{dispensing volume of the second nozzle }{\begin{matrix}total dispensing volume of the \\ first nozzle and the second nozzle\end{matrix}}} \times wafer radius .$$

For example, when the dispensing volume of the second nozzle 232 is 50% of the total dispensing volume, the horizontal distance D between the first nozzle 231 and the second nozzle 232 is 71% of the wafer radius. Referring to FIG. 2C, a schematic diagram showing the position of the second nozzle 232 for a 12-inch wafer at 50% dispensing volume is provided. As shown in FIG. 2C, when the first nozzle 231 is located at a position above a center of the wafer, the second nozzle should be located away from the first nozzle 231 for a horizontal distance of 106 mm (i.e., 71% of the wafer radius of a 12-inch wafer). In another example, when the dispensing volume of the second nozzle 232 accounts for 30% of the total dispensing volume (i.e., the dispensing volume of the first nozzle 231 is 70% of the total dispensing volume), the horizontal distance D between the first nozzle 231 and the second nozzle 232 may be 84% of the wafer radius.

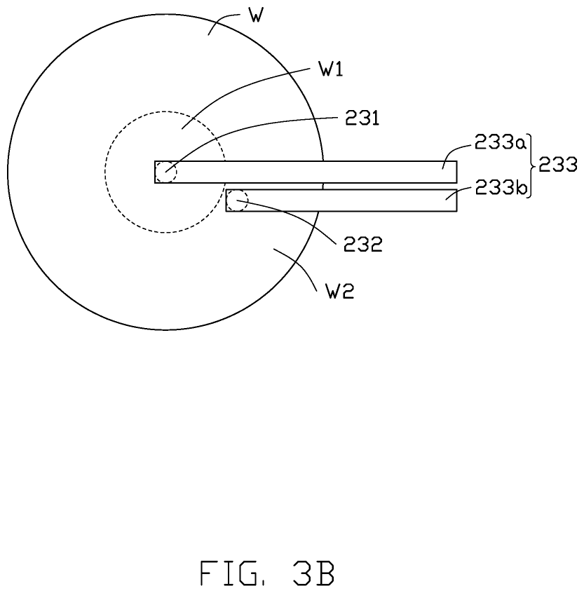

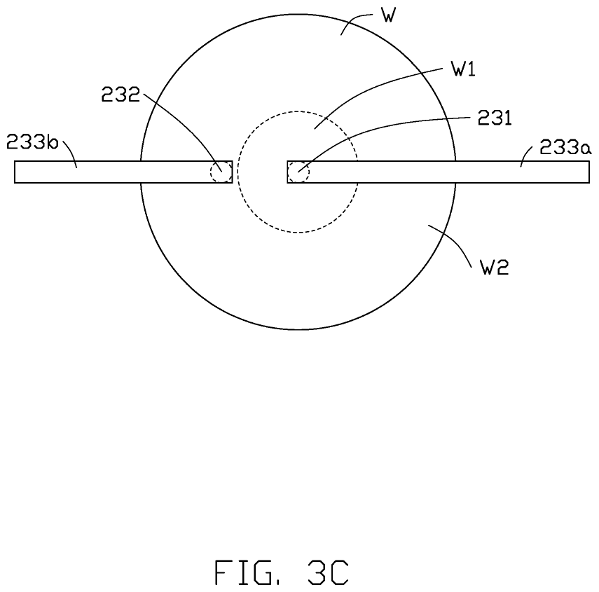

Referring to FIGS. 3A to 3C, a schematic diagram of the photoresist coating system and top views of first nozzle and the second nozzle of the photoresist dispensing module according to other implementations are illustrated. In the implementation shown in FIG. 3A, the first nozzle 231 and the second nozzle 232 are respectively connected to a first pipeline 233a and a second pipeline 233b of the photoresist pipeline assembly 233. The dispensing arm assembly 235 includes a first arm 235a and a second arm 235b respectively accommodating the first pipeline 233a and the second pipeline 233b. The first pipeline 233a and the second pipeline 233b are respectively surrounded by a first sleeve 234a and a second sleeve 234b of the water sleeve assembly 234. The arm motor assembly 236 includes a first motor 236a and a second motor 236b respectively coupled to the first arm 235a and the second arm 235b of the dispensing arm assembly 235. In this implementation, the positions of the first nozzle 231 and the second nozzle 232 are independently displaced by the first arm 235a and the second arm 235b of the dispensing arm assembly 235. Therefore, the horizontal distance D between the first nozzle 231 and the second nozzle 232 can be adjusted to meet various operational requirements of the spinning coating process. The first nozzle 231 and the second nozzle 232 may be adjacently disposed above the wafer W, as shown in FIG. 3B. In some implementations, the first nozzle 231 and the second nozzle 232 may be separately disposed above the wafer W, as shown in FIG. 3C.

Therefore, an implementation of the present disclosure provides a photoresist dispensing module for dispensing a photoresist solution onto a wafer. The photoresist dispensing module can be referred to the photoresist dispensing module 230 shown in FIGS. 2A to 3C. As shown in FIGS. 2A and 2B, the photoresist dispensing module 230 includes a first nozzle 231, a second nozzle 232, and a photoresist pipeline assembly 233 coupled to the first nozzle 231 and the second nozzle 232. The first nozzle 231 is configured to dispense the photoresist solution to a first portion W1 of the wafer W; and the second nozzle 232 is configured to dispense the photoresist solution to a second portion W2 of the wafer W. The photoresist pipeline assembly 233 is configured to supply the photoresist solution to the first nozzle 231 and the second nozzle 232. The photoresist pipeline assembly 233 may include a first pipeline 233a and a second pipeline 233b. The first pipeline 233a is coupled to the first nozzle 231 and configured to supply the photoresist solution to the first nozzle 231. The second pipeline 233b is coupled to the second nozzle 232 and configured to supply the photoresist solution to the second nozzle 232. The photoresist dispensing module 230 may further include a dispensing arm assembly 235, a water sleeve assembly 234, and an arm motor assembly 236. The dispensing arm assembly 235 is coupled to the photoresist pipeline assembly 233 to move the first nozzle 231 and the second nozzle 232. As shown in FIGS. 3A to 3C, the dispensing arm assembly 235 may include a first arm 235a coupled to the first pipeline 233a and a second arm 235b coupled to the second pipeline 233b. The first arm 235a of the dispensing arm assembly 235 is configured to move the first nozzle 231; and the second arm 235b of the dispensing arm assembly 235 is configured to move the second nozzle 232. The water sleeve assembly 234 surrounds the photoresist pipeline assembly 233. The water sleeve assembly 234 may include a first sleeve 234a surrounding the first pipeline 233a and a second sleeve 234b surrounding the second pipeline 233b. The arm motor assembly 236 is coupled to the dispensing arm assembly 235 and configured to move the dispensing arm assembly 235. The arm motor assembly 236 may include a first motor 236a coupled to the first arm 235a and a second motor 236b coupled to the second arm 235b. Preferably, the first nozzle 231 is configured to dispense the photoresist solution to a center portion of the wafer W, and the second nozzle 232 is configured to dispense the photoresist solution to an edge portion of the wafer W.

Another implementation of the present disclosure provides a photoresist coating system for coating a photoresist solution onto a wafer. The photoresist coating system can be referred to the photoresist coating system 200 in FIGS. 2A to 3C. As shown in FIGS. 2A to 3C, the photoresist coating system 200 includes a spin cup 210, a chuck 220, and a photoresist dispensing module 230. The spin cup 210 is configured to accommodate the wafer W. The chuck 220 is configured to hold the wafer W in the spin cup 210. The photoresist dispensing module 230 is configured to dispense the photoresist solution onto the wafer W. The photoresist coating system 200 may further include a thinner dispensing module 260, an edge bead removal (EBR) module 250, and a spin motor 240. The thinner dispensing module 260 is configured to dispense a thinner solution to the wafer W. The EBR module 250 is configured to clean edge beads formed by excess photoresist solution on a bevel or a backside of the wafer W. The spin motor 240 is coupled to the chuck 220 and configured to rotate the chuck 220 to rotate the wafer W. The spin cup 210 includes a drain hole 270 and an exhaust hole 280. The drain hole 270 is configured to drain liquids out of the spin cup 210. The exhaust hole 280 is configured to exhaust air out of the spin cup 210. The photoresist dispensing module 230 of the photoresist coating system 200 can be referred to previous implementation without further description herein.

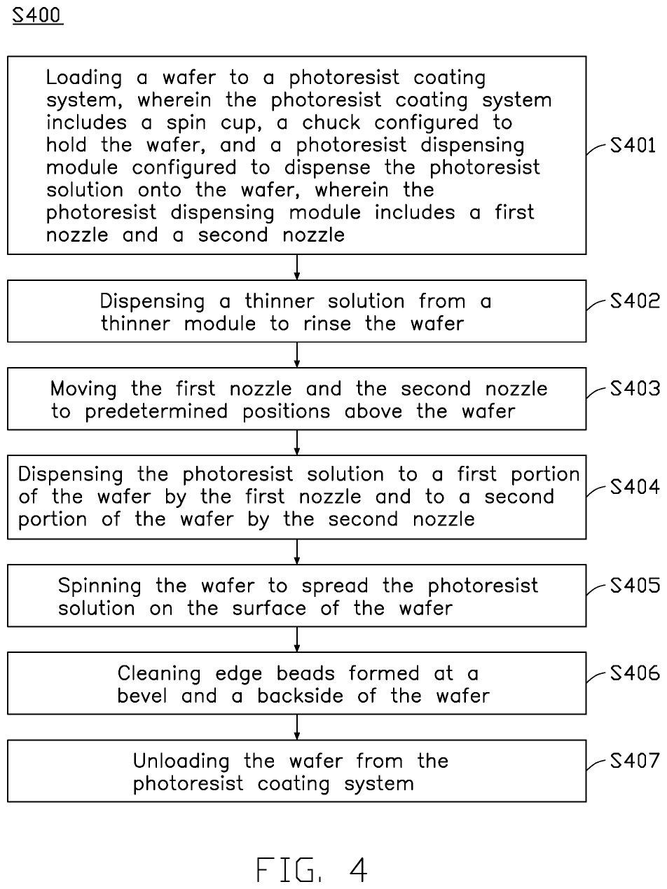

Yet another implementation of the present disclosure also provides a method for spin coating a photoresist solution onto a wafer. Referring to FIG. 4, a flow chart of the method is illustrated. As shown in FIG. 4, the method S400 includes actions S401 to S407.

In action S401, the wafer is loaded to a photoresist coating system. The photoresist coating system can be referred to the photoresist coating system 200 of FIGS. 2A to 3C. The photoresist coating system 200 includes a spin cup 210 for accommodating the wafer, a chuck 220 disposed in the spin cup 210 and configured to hold the wafer, and a photoresist dispensing module 230 configured to dispense the photoresist solution onto the wafer. The photoresist dispensing module 230 includes a first nozzle 231 and a second nozzle 232. The wafer W is clamped on the chuck 220 of the photoresist coating system 200.

In action S402, a thinner solution is dispensed to the surface of the wafer W to rinse the wafer W. The thinner solution may be dispensed from a thinner dispensing module 260 of the photoresist coating system 200. The thinner solution may be propylene glycol methyl ether acetate (PGMEA). The thinner solution wets the surface of the wafer W to facilitate spreading of the photoresist solution on the wafer W. The wafer W may be spun on the chuck 220 to remove excess thinner solution on the wafer W after the rinsing process.

In action S403, the first nozzle 231 and the second nozzle 232 are moved to predetermined positions above the wafer W. The first nozzle 231 and the second nozzle 232 are moved by a dispensing arm assembly 235 of the photoresist dispensing module 230. The dispensing arm assembly 235 is driven by an arm motor assembly 236. In the implementation shown in FIG. 2B, the first nozzle 231 is moved to a center position above the wafer W, and the position of the second nozzle 232 may be determined by an equation

$$D = \sqrt{\frac{dispensing volume of the second nozzle }{\begin{matrix}total dispensing volume of the \\ first nozzle and the second nozzle\end{matrix}}} \times wafer radius ,$$

wherein D is the horizontal distance between the first nozzle 231 and the second nozzle 232.

In action S404, the photoresist solution is dispensed to a first portion of the wafer W by the first nozzle 231 and to a second portion of the wafer W by the second nozzle 232. As shown in FIGS. 2B, 3B and 3C, the first nozzle 231 dispenses the photoresist solution to the first portion W1 of the wafer W; and the second nozzle 232 dispenses the photoresist solution to the second portion W2 of the wafer W. The first nozzle 231 and the second nozzle 232 may simultaneously spray the photoresist solution. In some implementations, the second nozzle 232 may start to dispense 0.1 to 0.2 seconds later than the first nozzle 231.

During the dispensing process, the first nozzle 231 and the second nozzle 232 may also be moved by the dispensing arm assembly 235 for 1 to 3 times to adjust the positions of the nozzles. In the implementation shown in FIG. 3A, the first nozzle 231 and the second nozzle 232 are respectively moved by a first arm 235a and a second arm 235b of the dispensing arm assembly 235. The first nozzle 231 and the second nozzle 232 may be moved back and forth respectively by the first arm 235a and the second arm 235b within a horizontal range of 5 mm to 10 mm.

In action S405, the wafer W is rotated on the chuck 220 of the photoresist coating system 200 to spread the photoresist solution over the surface of the wafer W by centrifugal force. By using two nozzles (i.e., the first nozzle 231 and the second nozzle 232) to spray on the center and the edge portions of the wafer, the photoresist solution can be evenly spread on the entire surface of the wafer W to prevent fingering effect, without having to apply excess amount of the photoresist solution. In action 406, edge beads formed by the photoresist solution at a bevel and backside of the wafer W is cleaned by an edge bead removal (EBR) module 250 of the photoresist coating system 200. In action S407, the wafer W is unloaded from the photoresist coating system 200.

As described above, the photoresist coating system and the method of the implementations of the present disclosure use an extra nozzle to dispense photoresist solution on the edge portion of the wafer. Therefore, the photoresist coating system and method of the implementations of the present disclosure can reduce the usage of photoresist solution, and also improve the uniformity of photoresist coating by reducing fingering effect on the edge of the wafer.

The implementations shown and described above are only examples. Many details are often found in the art such as the other features of a photoresist coating system and a method thereof. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the implementations described above may be modified within the scope of the claims.

What is claimed is:

1. A photoresist dispensing module for dispensing a photoresist solution onto a wafer, the photoresist dispensing module comprising:
a first nozzle configured to dispense the photoresist solution to a first portion of the wafer;
a second nozzle configured to dispense the photoresist solution to a second portion of the wafer; and
a photoresist pipeline assembly coupled to the first nozzle and the second nozzle and configured to supply the photoresist solution to the first nozzle and the second nozzle.

2. The photoresist dispensing module of claim 1, wherein the photoresist pipeline assembly comprising:
a first pipeline coupled to the first nozzle and configured to supply the photoresist solution to the first nozzle; and
a second pipeline coupled to the second nozzle and configured to supply the photoresist solution to the second nozzle.

3. The photoresist dispensing module of claim 2, further comprising a dispensing arm assembly coupled to the photoresist pipeline assembly to move the first nozzle and the second nozzle, wherein the dispensing arm assembly comprises a first arm coupled to the first pipeline and a second arm coupled to the second pipeline.

4. The photoresist dispensing module of claim 3, further comprising a water sleeve assembly surrounding the photoresist pipeline assembly, wherein the water sleeve assembly comprises a first sleeve surrounding the first pipeline and a second sleeve surrounding the second pipeline.

5. The photoresist dispensing module of claim 3, further comprising an arm motor assembly coupled to the dispensing arm assembly and configured to move the dispensing arm assembly, wherein the arm motor assembly comprises a first motor coupled to the first arm and a second motor coupled to the second arm.

6. The photoresist dispensing module of claim 1, wherein the first nozzle is configured to dispense the photoresist solution to a center portion of the wafer, and the second nozzle is configured to dispense the photoresist solution to an edge portion of the wafer.

7. A photoresist coating system for coating a photoresist solution onto a wafer, comprising:
a spin cup configured to accommodate the wafer;
a chuck configured to hold the wafer; and
a photoresist dispensing module configured to dispense the photoresist solution onto the wafer, the photoresist dispensing module including:
a first nozzle configured to dispense the photoresist solution to a first portion of the wafer;
a second nozzle configured to dispense the photoresist solution to a second portion of the wafer; and
a photoresist pipeline assembly coupled to the first nozzle and the second nozzle and configured to supply the photoresist solution to the first nozzle and the second nozzle.

8. The photoresist coating system of claim 7, wherein the photoresist pipeline assembly of the photoresist dispensing module comprising:
a first pipeline coupled to the first nozzle and configured to supply the photoresist solution to the first nozzle; and
a second pipeline coupled to the second nozzle and configured to supply the photoresist solution to the second nozzle.

9. The photoresist coating system of claim 8, wherein the photoresist dispensing module further comprising a dispensing arm assembly coupled to the photoresist pipeline assembly to move the first nozzle and the second nozzle, and the dispensing arm assembly comprises a first arm coupled to the first pipeline and a second arm coupled to the second pipeline.

10. The photoresist coating system of claim 9, wherein the photoresist dispensing module further comprising a water sleeve assembly surrounding the photoresist pipeline assembly, and the water sleeve assembly comprises a first sleeve surrounding the first pipeline and a second sleeve surrounding the second pipeline.

11. The photoresist coating system of claim 9, wherein the photoresist dispensing module further comprising an arm motor assembly coupled to the arm assembly and configured to move the dispensing arm assembly, and the arm motor assembly comprises a first motor coupled to the first arm and a second motor coupled to the second arm.

12. The photoresist coating system of claim 7, wherein the first nozzle of the photoresist dispensing module is configured to dispense the photoresist solution to a center portion of the wafer, and the second nozzle of the photoresist dispensing module is configured to dispense the photoresist solution to an edge portion of the wafer.

13. The photoresist coating system of claim 7, further comprising a thinner dispensing module configured to dispense a thinner solution to the wafer.

14. The photoresist coating system of claim 7, further comprising an edge bead removal (EBR) module configured to clean edge beads formed by the photoresist solution on a bevel or a backside of the wafer.

15. The photoresist coating system of claim 7, further comprising a spin motor coupled to the chuck and configured to rotate the chuck.

16. The photoresist coating system of claim 7, wherein the spin cup comprises a drain hole configured to drain liquids out of the spin cup, and an exhaust hole configured to exhaust air out of the spin cup.

17. A method for spin coating a photoresist solution onto a wafer, comprising:
loading the wafer to a photoresist coating system, wherein the photoresist coating system comprises a spin cup configured to accommodate the wafer, a chuck configured to hold the wafer, and a photoresist dispensing module configured to dispense the photoresist solution onto the wafer, wherein the photoresist dispensing module comprises a first nozzle and a second nozzle;
dispensing the photoresist solution to a first portion of the wafer by the first nozzle and to a second portion of the wafer by the second nozzle; and
spinning the wafer to spread the photoresist solution over the surface of the wafer.

18. The method of claim 17, wherein after the wafer is loaded to the photoresist coating system, the method further comprising:
dispensing a thinner solution from a thinner module to rinse the wafer; and
moving the first nozzle and the second nozzle of the photoresist dispensing module to predetermined positions above the wafer.

19. The method of claim 17, wherein after the photoresist solution is spread over the surface of the wafer, the method further comprising:
cleaning edge beads formed at a bevel and a backside of the wafer; and
unloading the wafer from the photoresist coating system.

20. The method of claim 17, wherein the photoresist dispensing module further comprises a photoresist pipeline assembly coupled to the first nozzle and the second nozzle and configured to supply the photoresist solution to the first nozzle and the second nozzle, and the photoresist pipeline assembly comprises a first pipeline coupled to the first nozzle, and a second pipeline coupled to the second nozzle.
